(19) United States
(12) Patent Application Publication
(10) Pub. No.: US 2016/0071849 A1
(43) Pub. Date: Mar. 10, 2016

(54) Mode-Variant Adaptive Body Bias Scheme For Low-Power Semiconductors

(71) Applicant: Texas Instruments Incorporated, Dallas, TX (US)

(72) Inventor: Vipul Kumar Singhal, Karnataka (IN)

(21) Appl. No.: 14/624,323

(22) Filed: Feb. 17, 2015

Related U.S. Application Data
(60) Provisional application No. 62/047,146, filed on Sep. 8, 2014.

(51) Int. Cl. H01L 27/092; H03K 3/012

(52) U.S. Cl. CPC H01L 27/092; H03K 3/012

(57) ABSTRACT

A complementary metal oxide semiconductor (CMOS) device having an active mode and a standby mode. The CMOS device includes a first transistor having a first body, a second transistor having a second body, a first forward body bias voltage source, and a second forward body bias voltage source. The first forward body bias voltage source is coupled to the first body when the CMOS device is in the active mode, and is disconnected from the first body when the CMOS device is in the standby mode. The second forward body bias voltage source is coupled to the second body when the CMOS device is in the active mode, and is disconnected from the second body when the CMOS device is in the standby mode.

This application claims priority to U.S. Provisional Patent Application 62/047,146, filed Sep. 8, 2014, entitled MODE-VARIANT, ADAPTIVE BODY BIAS SCHEME FOR ULTRA-LOW POWER DESIGN, which is hereby expressly incorporated herein by reference for all that is disclosed.

### BACKGROUND

There is an ever-increasing demand for reducing power consumption in electronic devices. This is particularly true for sensor node devices in a network of interconnected devices. In such devices, low energy consumption translates to longer battery life, or being able to operate with a smaller and/or less expensive battery. Sensor node devices generally have a microcontroller that runs code from an embedded non-volatile memory. In order to support increasing computational needs and the requirement to reduce latency (i.e., increase the ability to respond quickly to an event), it is desirable for a microcontroller to run at a relatively high frequency (e.g., 8-16 MHz), while still maintaining low power consumption. Since most sensor applications are event driven, many sensor node microcontrollers, when not active, go into a standby mode in order to reduce the power consumption. Ideally, such devices would not consume any power in the standby mode. However, such devices typically need to operate sensors and associated circuitry in order to, e.g., sense when they are to exit standby mode and commence active operation. Otherwise they would never transition out of the standby mode. Operating such sensors and associated circuitry consumes power, albeit it much lower levels than active-mode power consumption in most cases.

In order to minimize the total energy consumption, it is important to reduce both the active mode power consumption and the standby mode power consumption, and to maintain an ability to switch between the modes with low latency and low transition energy.

Some low power microcontroller implementations exist, but have limitations. For example, some implementations aggressively address active mode power, but have higher standby mode power consumption and also do not support state retention. Accordingly, memory states are lost when the device transitions to the standby mode. Other implementations aggressively address the standby mode power dissipation, but have higher active mode power consumption, especially for code running out of a non-volatile memory.

### SUMMARY

A complementary metal oxide semiconductor (CMOS) device having an active mode and a standby mode is disclosed. The CMOS device includes a first transistor having a first body, a second transistor having a second body, a first forward body bias voltage source, and a second forward body bias voltage source. The first forward body bias voltage source is coupled to the first body when the CMOS device is in the active mode, and is disconnected from the first body when the CMOS device is in the standby mode. The second forward body bias voltage source is coupled to the second body when the CMOS device is in the active mode, and is disconnected from the second body when the CMOS device is in the standby mode.

### BRIEF DESCRIPTION OF THE DRAWINGS

FIGS. 1a-1c are simplified voltage graphs representing the threshold voltage of a MOSFET transistor, illustrating three different ways of switching the threshold voltage between two levels.

FIGS. 2a and 2b are simplified schematic diagrams representing a circuit for selectively applying body bias to a CMOS transistor pair based on whether the device is in active mode or standby mode.

FIG. 3 is a cross-sectional view of a CMOS device.

FIG. 4 is a flowchart representing an illustrative method of operating a CMOS device in the standby mode.

FIG. 5 is a flowchart representing an illustrative method of transitioning a CMOS device from the active mode to the standby mode.

### DETAILED DESCRIPTION

The present disclosure is directed generally towards devices wherein certain transistors in said device employ different threshold voltages depending on whether the device is in active mode or standby mode in order to minimize power consumption in both active mode and standby mode. More specifically, a low threshold voltage is maintained when the device is in active mode, and a high threshold voltage is maintained when the device is in standby mode. Maintaining a low threshold voltage in active mode allows the device to operate at a lower power supply level V_{DD} while maintaining high performance. Maintaining a high threshold voltage in standby mode minimizes leakage current, i.e., current conducted by a transistor when it is turned off. For purposes of explanation, aspects of the present disclosure will be described with respect to metal oxide semiconductor field-effect transistors (MOSFETs), and, in particular, complementary metal oxide semiconductor (CMOS) devices, but it is to be understood that aspects of this disclosure can be applied to other types of transistors as well.

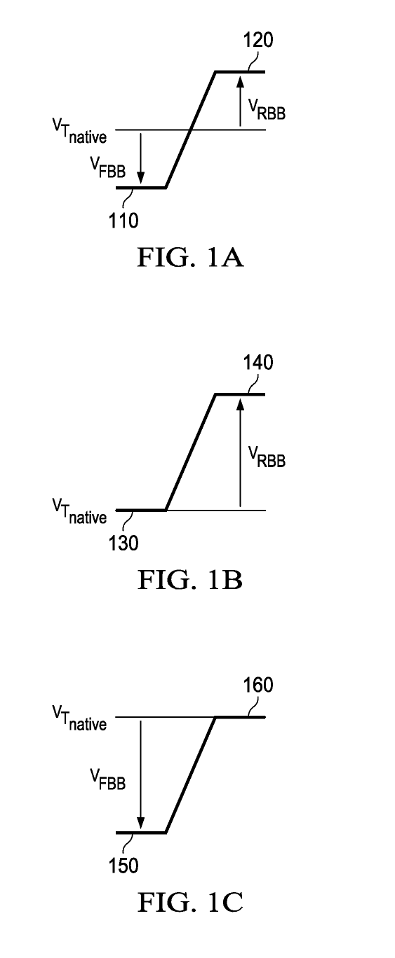

In an illustrative embodiment, the different threshold voltages that are employed depending on whether the device is in active mode or standby mode are achieved by applying a forward body bias and/or a reverse body bias to the body of the transistor. FIGS. 1a-1c are simplified voltage graphs representing the threshold voltage of a MOSFET transistor, illustrating three different ways of switching the threshold voltage between two levels. In FIG. 1a, a forward body bias is applied to the transistor when the device is in active mode to achieve a relatively low threshold voltage 110. Thus the active-mode threshold voltage 110 is lower than the native threshold voltage V_{T}_{ₙₐₜᵢᵥₑ} by the amount of the forward body bias V_{FBB}. In the standby mode, a reverse body bias is applied to the transistor to achieve a higher threshold voltage 120. Thus the standby-mode threshold voltage 120 is higher than the native threshold voltage V_{T}_{ₙₐₜᵢᵥₑ} by the amount of the reverse body bias V_{RBB}.

In FIG. 1b, no body bias is applied to the transistor when the device is in active mode. Thus the active-mode threshold voltage 130 is equal to the transistor's native threshold voltage V_{T}_{ₙₐₜᵢᵥₑ}. In the standby mode, a reverse body bias is applied to the transistor to achieve a higher threshold voltage 140. Thus the standby-mode threshold voltage 140 is higher than the native threshold voltage V_{T}_{ₙₐₜᵢᵥₑ} by the amount of the reverse body bias V_{RBB}.

In FIG. 1c, when the device is in standby mode, no body bias is applied to the transistor. Thus the standby-mode threshold voltage 160 is equal to the transistor's native threshold voltage V_{T}_{ₙₐₜᵢᵥₑ}. When the device is active, a forward body bias is applied to the transistor to achieve a lower threshold voltage 150. Thus the active-mode threshold voltage 150 is lower than the native threshold voltage V_{T}_{ₙₐₜᵢᵥₑ} by the amount of the reverse body bias V_{FBB}. In applications where the device is likely to sit in standby mode a high proportion of the time relative to the amount of time it is active, the scheme represented in FIG. 1c is preferable to the schemes of FIGS. 1a and 1b because bias generation can be shut down in standby mode. Bias generation significantly adds to the standby current. Hence applying forward body bias in active mode is much more energy efficient than applying reverse body bias in standby mode.

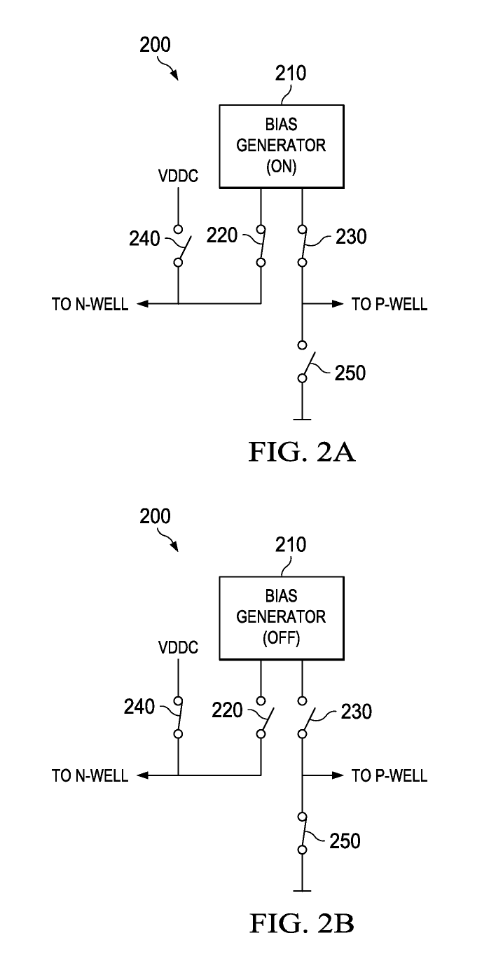

FIGS. 2a and 2b are simplified schematic diagrams representing a circuit 200 for selectively applying body bias to a complementary metal oxide semiconductor (CMOS) transistor pair based on whether the device is in active mode or standby mode. In an illustrative embodiment, FIGS. 2a and 2b correspond to the scheme represented by FIG. 1c. In that illustrative embodiment, FIG. 2a represents the state of the circuit 200 when the device is in active mode. When the device is active, switches 220 and 230 are closed to couple the bias generation circuit 210 to the N-well and P-well of the CMOS transistor pair in order to apply a forward body bias to the transistor pair and establish a lower threshold voltage. Switch 240 is opened to disconnect the voltage supply V_{DD} from the N-well and switch 250 is opened to disconnect the P-well from ground. Note that FIGS. 2a and 2b depict the provision of a body bias voltage to a CMOS transistor pair and thus the body bias voltage is applied to both the N-well and the P-well of the CMOS device. It is to be understood that other embodiments pertain to other types of transistors, including, e.g., non-complementary transistor types such as NMOS and PMOS transistors, as well as other types of field effect transistors (FETs). in such non-complementary transistor devices, the body bias voltage would be applied to either (rather than both) an N-well or a P-well of the device, depending on whether the transistor is a p-type transistor or an n-type transistor.

FIG. 2b represents the state of the circuit 200 when the device is in standby mode. When the device is in standby, the bias generation circuit 210 is turned off and switches 220 and 230 are opened to disconnect the bias generation circuit 210 from the n-well and p-well of the CMOS transistor pair. Disconnecting the bias generation circuit 210 prevents the bias generation circuit 210 from sinking or sourcing current when the device is in standby mode. Switch 240 is closed to couple the voltage supply V_{DD} to the n-well and switch 250 is closed to couple the p-well to ground. Thus no forward body bias is applied to the CMOS transistor pair and the standby-mode threshold voltage is equal to the native threshold voltage V_{T}_{ₙₐₜᵢᵥₑ} of the CMOS transistor pair. In an illustrative embodiment, the bias generation circuit 210, in addition to being disconnected from the bodies (n-well and p-well) of the transistor pair, is turned off, thus saving bias generation power.

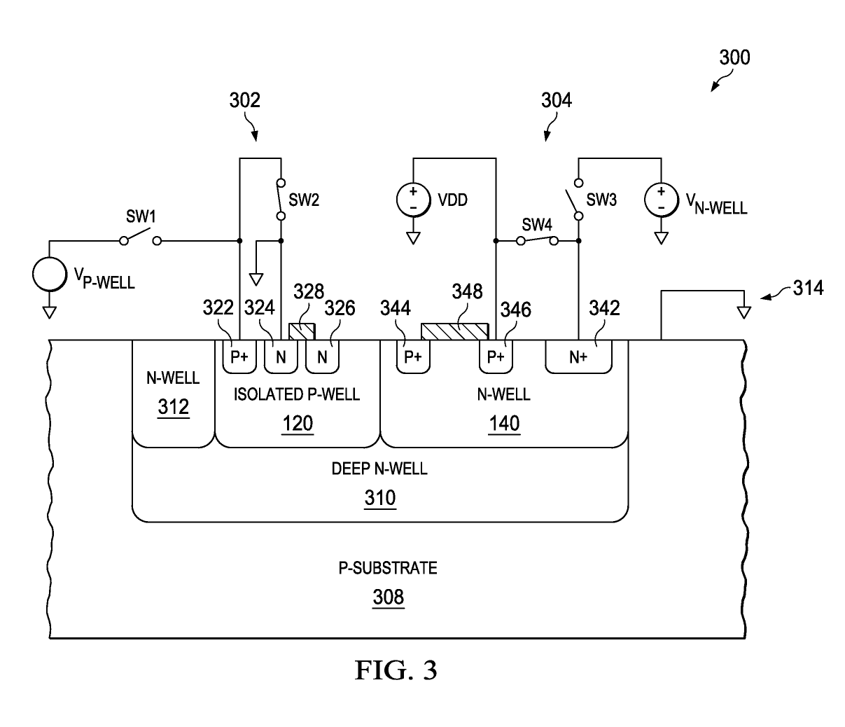

FIG. 3 is a cross-sectional view of a complementary metal-oxide semiconductor (CMOS) device 300 that is operable to employ a first, lower, threshold voltage when the device 300 is in active mode, and to employ a second, higher, threshold voltage when the device is in standby mode. CMOS device 300 includes a first transistor 302 and a second transistor 304. In the illustrative embodiment represented by FIG. 3, the first transistor 302 is an n-channel device, which is sometimes referred to herein as an NMOS transistor. The second transistor 304 is a p-channel device, which is sometimes referred to herein as a PMOS transistor. The transistors 302, 304 are housed in a substrate 308, which in the example of FIG. 3 is a p-substrate, meaning that it is doped positive. The transistors 302, 304 are separated from the substrate 308 by a deep well 310 and a well 312. In the example of FIG. 3, both the deep well 310 and the well 312 are n-wells, meaning that they are doped negative. In the example of FIG. 3, the substrate 308 is coupled to ground by way of a ground connection 314. The first transistor 302 is located in an isolated, positively doped, well 320. The isolated p-well 320 makes up what is known as the body portion of transistor 302. The second transistor 304 is located in a well 340 that is doped with a negative charge. The n-well 340 comprises the body portion of transistor 304. N-well 312 and deep n-well 310 provide the isolation for the isolated p-well 320. As can be seen in FIG. 3, the n-well 340 is not isolated. In the illustrative example of FIG. 3, the transistors 302, 304 are housed in a p-substrate 308 and the p-well 320 is isolated by an n-well 312 and a deep n-well 310. However, it will be appreciated that this example is illustrative only and that the roles can be reversed. That is, the transistors 302, 304 could likewise be housed in an n-substrate and an n-well could be isolated by a p-well and a deep p-well, for example. Furthermore, aspects of the present disclosure can also be implemented in stand-alone (non-complementary) transistors such as NMOS or PMOS transistors, as well as in non-MOS field effect transistors (FETs). Additionally, while FIG. 3 shows just one NMOS transistor 302 and one PMOS transistor 304, in practice there could be any number of NMOS and PMOS transistors.

The isolated p-well 320 has three doped implants, or regions, that serve as nodes, or contacts, of the first transistor 302. The p-well body contact 322 is a highly positively doped (P+) region that serves as the body contact of the first transistor 302. The drain 324 and source 326 are regions of the isolated p-well 320 that are doped with a negative charge, i.e., the opposite charge of the isolated p-well 320. A gate material 328 extends between the drain 324 and the source 326 in a conventional manner. Similarly, n-well 340 has three doped implants, or regions, that serve as nodes, or contacts, of the second transistor 304. The n-well body contact 342 is a highly negatively doped (N+) region that serves as the body contact of the second transistor 304. The drain 344 and a source 346 are regions of the n-well 340 that are doped with a positive charge, i.e., the opposite charge of the n-well 340. A gate material 348 extends between the drain 344 and the source 346 in a conventional manner. In the illustrative configuration of FIG. 3, the drain 324 of the first transistor 302 is coupled to ground and the source 346 of the second transistor 304 is coupled to a power supply voltage V_{DD}. The power supply voltage V_{DD} is a voltage that is present regardless of the state of the CMOS device 300.

The transistors 302 and 304 support a standard voltage threshold (SVT) and a high voltage threshold (HVT). The threshold voltages are established based on body bias voltages applied to the p-well 320 and the n-well 340. In an illustrative embodiment, when the device 300 is in active mode, a forward body bias (FBB) is applied to the body contacts 322, 342 of the p-well 320 and the n-well 340, which gives a lower voltage threshold, also referred to herein as the standard voltage threshold (SVT). When the device is in standby mode, no forward body bias is applied to the body contacts 322, 342, which results in a higher voltage threshold, also referred to herein as the high voltage threshold (HVT). As described with respect to FIG. 1c, this scheme is particularly effective in applications where the device is likely to sit in standby mode a high proportion of the time relative to the amount of time it is active. Switches SW1-SW4 facilitate the selective coupling of the forward body bias voltage sources V_{p-well} and V_{n-well} to the p-well 320 and the n-well 340, respectively, depending on whether the device 300 is in active mode or standby mode. In an alternative embodiment, when the device 300 is in active mode, the forward body bias is applied to only one of the NMOS transistor 302 and the PMOS transistor 304, as opposed to both of them.

The body contact 322 of the first transistor 302 is coupled to switches SW1 and SW2 which selectively connect the p-well 320 to the voltage source V_{p-well} or to ground. Switch SW1 is coupled between the voltage source V_{p-well} and the body contact 322 of p-well 320. Switch SW2 is coupled between ground and the body contact 322 of the p-well 340. Similarly, the body contact 342 of the second transistor 304 is coupled to switches SW3 and SW4 which selectively connect the n-well 340 to the voltage source Vn_{-well} or to the power supply voltage V_{DD}. Switch SW3 is coupled between the voltage source V_{n-well} and the body contact 342 of n-well 340. Switch SW4 is coupled between the power supply V_{DD} and the body contact 342 of the n-well 340. When the device 300 is active, switch SW1 is closed and switch SW2 is opened in order to connect the p-well 320 to V_{p-well}, which provides the forward body bias to the first transistor 302, thereby implementing the lower threshold voltage level, i.e., the standard voltage threshold SVT. Similarly, when the device 300 is active, switch SW3 is closed and switch SW4 is opened in order to connect the n-well 340 to V_{n-well}, which provides the forward body bias to the second transistor 304, thereby implementing the lower threshold voltage level. The switches SW1-SW4 are controlled by a microcontroller or the like (not shown) based on whether the device is in active mode or standby mode. The microcontroller will cause one of the switches SW1 or SW2 to be open and the other switch to be closed. Both switches will not be open or closed at the same time except possibly during a state change of the switches. Similarly, at any given time, one of the switches SW3 or SW4 will be open and the other will be closed.

In an illustrative embodiment, the microcontroller also controls the voltage sources V_{p-well} and V_{n-well} in order to select an appropriate bias voltage to be applied to the wells 320 and 340. Illustratively, the voltage level of the n-well forward body bias voltage V_{n-well} is less than V_{DD}, and the voltage level of the p-well forward body bias voltage V_{p-well} is less than V_{n-well} but greater than zero. Thus when the transistors 302, 304 are active, the forward body bias voltages set the voltage thresholds of the transistors 302 and 304 to the standard voltage threshold (SVT), which is lower than the high voltage threshold (HVT) that is used when the device 300 is in standby mode. In order to eliminate latch-up susceptibility, in some illustrative embodiments the maximum FBB voltages are limited. For example, in one embodiment, the FBB voltages are limited to 0.45V with a margin of 0.05V, so the FBB voltages are less than 0.4V.

When the device 300 is in standby mode, the forward body bias of the CMOS device 300 is removed by decreasing the bias voltage of the p-well 320 and increasing the bias voltage of the n-well 340 in order to achieve the high voltage threshold HVT, which, as explained, is higher than the standard threshold voltage SVT that is employed when the device is active. Thus when the device 300 is active, switch SW1 is opened and switch SW2 is closed in order to disconnect the p-well 320 from V_{p-well} and connect it to ground. Similarly, switch SW3 is opened and switch SW4 is closed in order to disconnect the n-well 340 from V_{n-well} and connect it to V_{DD}. With the p-well 320 connected to ground and the n-well 340 connected to V_{DD}, no forward body bias is applied to the device 300, thereby implementing the higher threshold voltage level HVT. In an illustrative embodiment, when the bias voltage sources V_{n-well} and V_{p-well} are disconnected from the n-well 340 and p-well 320, respectively, they are also powered down, as will be described in more detail below. When the voltage sources V_{n-well} and V_{p-well} are described herein as being disconnected from the transistors 302, 304, in an illustrative embodiment this disconnection refers to a physical disconnection. But in other embodiments, such disconnection may simply mean that the voltage sources do not sink or source current, though they may remain physically connected to the transistors 302, 304. Also, in an alternative embodiment, the voltage sources V_{n-well} and V_{p-well} are left connected in standby but are turned off.

In certain prior art threshold voltage adjustment schemes, body bias voltage sources remain connected to the body of a transistor or transistors during both active mode and standby mode, and the voltage provided by such voltage sources is adjusted depending on whether the device is in active mode or standby mode. Illustrative embodiments represented by FIG. 3, wherein the body bias voltage sources V_{n-well} and V_{p-well} are disconnected from the body contacts 342 and 322, respectively, in standby mode, have multiple advantages over such prior art schemes. For example, in some such prior art schemes, a body bias voltage source, such as an n-well body bias voltage source, continues to provide bias voltage at significant levels, for example, at voltages approximately equal to V_{DD}, in standby mode. In contrast, in FIG. 3, the n-well body bias voltage source V_{n-well} is turned off, in addition to being disconnected via switch SW3, in standby mode. This results in significant power savings. Also, for example, in some prior art schemes, a body bias voltage source, such as a p-well body bias voltage source, remains on and connected to the p-well in standby mode but generates zero volts. Although the source generates 0 V, current still flows through such a voltage source, which consumes power. In contrast, in FIG. 3, the p-well body bias voltage source V_{p-well} is turned off, in addition to being disconnected via switch SW1, in standby mode. Thus no current flows through the voltage source, resulting in further power savings.

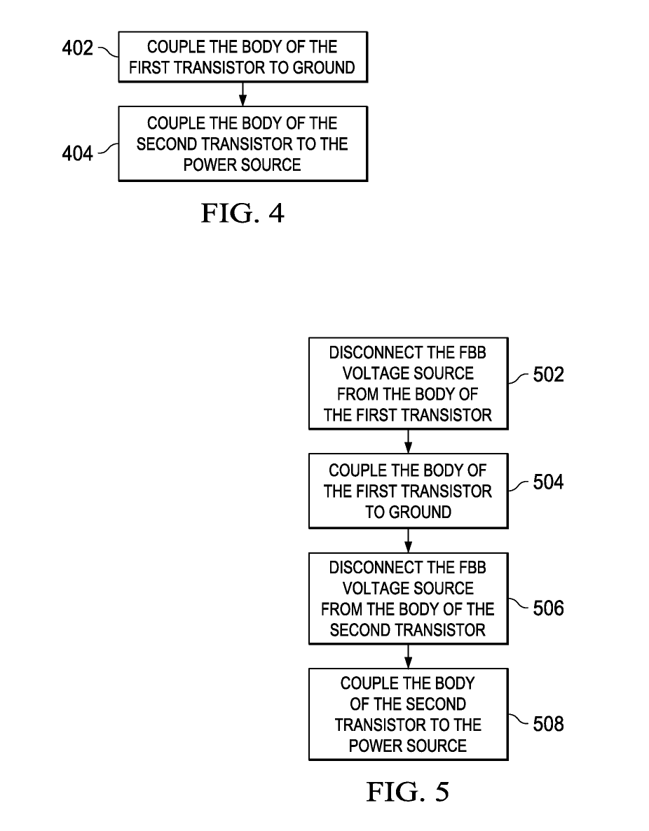

FIG. 4 is a flowchart representing an illustrative method of operating a CMOS device such as CMOS device 300. At step 402, the body 320 of the first transistor 302 is coupled to ground. At step 404, the body 340 of the second transistor 304 is to the power source V_{DD}. As described above, the power source is a source that stays active regardless of the mode of operation (i.e., active or standby) of the device.

FIG. 5 is a flowchart representing an illustrative method of changing the mode of a CMOS device such as CMOS device 300 from the active mode to the standby mode. At step 502, the forward body bias voltage source V_{p-well} is disconnected from the body 320 of the first transistor 302. At step 504, the body 320 of the first transistor 302 is coupled to ground. At step 506, the forward body bias voltage source V_{n-well} is disconnected from the body 340 of the second transistor 304. At step 508, the body 340 of the second transistor 304 is coupled to the power source V_{DD}.

While illustrative and presently preferred embodiments of integrated circuits have been described in detail herein, it is to be understood that the inventive concepts may be otherwise variously embodied and employed and that the appended claims are intended to be construed to include such variations except insofar as limited by the prior art.

What is claimed is:

1. A complementary metal oxide semiconductor (CMOS) device having an active mode and a standby mode, the CMOS device comprising:
a first transistor having a first body;
a second transistor having a second body;
a first forward body bias voltage source that is coupled to the first body when the CMOS device is in the active mode, and that is disconnected from the first body when the CMOS device is in the standby mode;
a second forward body bias voltage source that is coupled to the second body when the CMOS device is in the active mode, and that is disconnected from the second body when the CMOS device is in the standby mode.

2. The CMOS device of claim 1 further comprising a power source, wherein the power source is coupled to the second body when the CMOS device is in the standby mode.

3. The CMOS of claim 2, wherein the power source is disconnected from the second body when the CMOS device is in the active mode.

4. The CMOS device of claim 1 further comprising a ground, wherein the ground is coupled to the first body when the CMOS device is in the standby mode.

5. The CMOS device of claim 4 wherein the ground is disconnected from the first body when the CMOS device is in the active mode.

6. The CMOS device of claim 1, wherein the first body comprises a p-well.

7. The CMOS device of claim 1, wherein the second body comprises an n-well.

8. The CMOS device of claim 1, wherein the first forward body bias voltage source and the second forward body bias voltage source are turned off when the CMOS device is in the standby mode.

9. A method of operating a complementary metal oxide semiconductor (CMOS) device in a standby mode, the CMOS device comprising a first transistor and a second transistor, the method comprising:
coupling a body of the first transistor to a ground; and
coupling a body of the second transistor to a power source.

10. The method of claim 9, further comprising disconnecting a forward body bias voltage source from the body of the first transistor.

11. The method of claim 10, further comprising turning off the forward body bias voltage source.

12. The method of claim 9, further comprising disconnecting a forward body bias voltage source from the body of the second transistor.

13. The method of claim 12, further comprising turning off the forward body bias voltage source.

14. The method of claim 9, wherein coupling the body of the first transistor to a ground comprises disconnecting a forward body bias voltage source from the body of the first transistor and coupling the body of the first transistor to ground.

15. The method of claim 9, wherein coupling the body of the second transistor to the power source comprises disconnecting a forward body bias voltage source from the body of the second transistor and coupling the body of the second transistor to the power source.

16. The method of claim 9, wherein the voltage of the power source is constant irrespective of the mode of the CMOS device.

17. A method of changing a mode of a CMOS device from an active mode to a standby mode, the CMOS device comprising a first transistor and a second transistor, the method comprising:
disconnecting a forward body bias voltage source from a body of the first transistor;
coupling the body of the first transistor to a ground;
disconnecting a forward body bias voltage source from a body of the second transistor; and
coupling the body of the second transistor to a power source.

18. The method of claim 17, wherein the voltage of the power source is constant irrespective of the mode of the CMOS device.

19. The method of claim 17, wherein the body of the first transistor comprises a p-well.

20. The method of claim 17, further comprising turning off the forward body bias voltage source.
